(19) United States
(12) Patent Application Publication
(10) Pub. No.: US 2010/0002417 A1
(43) Pub. Date: Jan. 7, 2010

(54) BACK BEZEL FOR USE IN A BACKLIGHT MODULE STRUCTURE, THE BACKLIGHT MODULE STRUCTURE, AND THE METHOD FOR MANUFACTURING THE BACK BEZEL

(75) Inventors: Wei-Chih CHIU, Hsinchu (TW); Ching-Kun LAI, Hsinchu (TW)

Correspondence Address: PATTERSON, THUENTE, SKAAR & CHRISTENSEN, P.A., 4800 IDS CENTER, 80 SOUTH 8TH STREET, MINNEAPOLIS, MN, 55402-2100, US

(73) Assignee: AU Optronics Corp., Hsinchu (TW)

(21) Appl. No.: 12/402,194

(22) Filed: Mar. 11, 2009

(30) Foreign Application Priority Data
Jul. 2, 2008 (TW) 097124944

(51) Int. Cl. G02F 1/13357; H05K 5/04

(52) U.S. Cl. 362/97.1; 361/679.01

(57) ABSTRACT

A backlight module structure for use in a liquid crystal display, a back bezel for use in the backlight module structure, and a method of manufacturing the back bezel are disclosed. The backlight module structure comprises the back bezel and a base. The back bezel has a surface and a recessed area formed on the surface. The base has at least one bottom portion and at least one fixing portion. The bottom portion is disposed on the recessed area. The fixing portion is disposed on the bottom portion, extending outwards from the bottom portion and protruding above the surface of the back bezel. Moreover, the back bezel is formed by stamping the surface to form a recessed area extending inwards from the surface.

This application claims priority to Taiwan Patent Application No. 097124944 filed on Jul. 2, 2008, the content of which is incorporated herein by reference in its entirety.

### CROSS-REFERENCES TO RELATED APPLICATIONS

Not applicable.

### BACKGROUND OF THE INVENTION

1. Field of the Invention

The present invention relates to a backlight module structure for use in a liquid crystal display (LCD) and a method for manufacturing the backlight module structure; and particularly, the present invention relates to a back bezel capable of concealing fixing elements in a backlight module structure and a method for manufacturing the back bezel.

2. Descriptions of the Related Art

There are two categories of backlight modules that are used in LCD screens: side-light type and direct-light type. Side-light backlight modules are often found in small and medium sized panels. Using the light guide in the side-light backlight modules, however, makes it impossible to provide a lightweight product when they are used in large-sized screens. Therefore, super-sized backlight modules typically utilize direct-light backlight modules.

FIG. 1 depicts a structure of a conventional direct-light backlight module 1. The backlight module 1 has a back bezel 10, a reflecting sheet 11, a plurality of bases 12 and a plurality of lamps 13. The reflecting sheet 11, which has higher reflectivity than that of the back bezel 10, is attached on the top surface of the back bezel 10 and adapted to reflect light projected on the back bezel 10 to enhance luminance of the backlight module 1. The base 12 has a bottom portion 121, a plurality of lamp holders 122, at least one spacer pin 123 and at least one clamp 124. The clamp 124 is disposed on the bottom surface of the bottom portion 121 and adapted to secure the base 12 to the top surface of the back bezel 10. The lamp holders 122 and the spacer pin 123 are disposed on the top surface of the bottom portion 121. Each of the lamp holders 122 is adapted to hold a lamp 13, while the spacer pin 123 is typically used to support an optical film set.

The base 12 of such a backlight module 1 is easy to assemble, i.e., the base 12 can be assembled by simply snapping the clamp 124 thereof into the corresponding through-holes on the back bezel 10. However, because the whole bottom portion 121 overlaps the top surface of the reflecting sheet 11, the areas where the portions of the reflecting sheet 11 are shielded will result in a lower reflectivity than that of the surrounding areas. Consequently, there will be a non-uniform optical performance with partial dark areas when viewing the liquid crystal screen.

In view of this, efforts still have to be made in the art to overcome the problems of both insufficient and non-uniform luminance in conventional backlight module structures.

### SUMMARY OF THE INVENTION

One objective of this invention is to provide a backlight module structure for use in an LCD. The backlight module structure is able to improve optical performance of the backlight module by reducing the shielded area of the reflective sheet shielded by the lamps and optical film securing set.

This invention provides a back bezel and a backlight module structure comprising the same. The backlight module structure comprises the back bezel, a base and a reflecting sheet. The back bezel has a surface and a recessed area. The recessed area extends inwards from the surface and is adapted to receive at least one portion of the base. The base has at least one bottom portion disposed in the recessed area and at least one fixing portion disposed on the bottom portion. The fixing portion extends outwards from the bottom portion and protrudes above the surface.

The reflecting sheet has a plurality of openings disposed on the reflecting sheet. When the reflecting sheet is attached to the surface of the back bezel, the reflecting sheet is adapted to cover the top surface of the bottom portions, while the fixing portions are adapted to protrude outwards through the openings.

Another objective of this invention is to provide a method for manufacturing a back bezel for use in a backlight module. The method comprises the following steps: providing a back bezel with a surface; and stamping the back bezel from the surface to form a recessed area extending inwards from the surface.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1 is a schematic view of a conventional backlight module structure; and

FIG. 2 is a schematic view of a backlight module structure according to an embodiment of this invention.

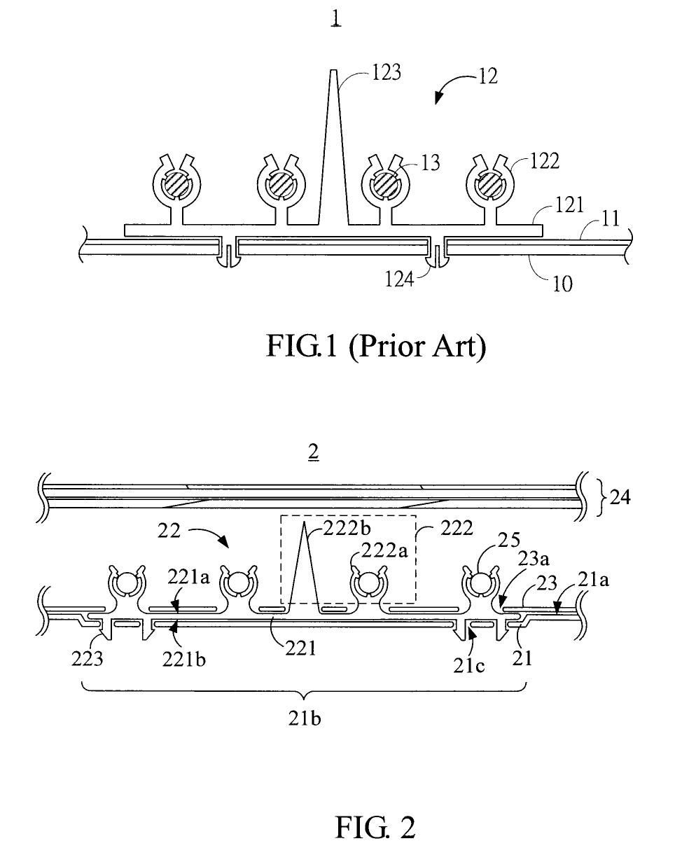

### DESCRIPTION OF THE PREFERRED EMBODIMENT

FIG. 2 illustrates a schematic view of a backlight module structure according to an embodiment of this invention. The backlight module 2 of this invention comprises a back bezel 21, a base 22 and a reflecting sheet 23. The back bezel 21 has a surface 21a and a recessed area 21b. The recessed area 21b is formed by recessing the back bezel 21 inwards from the surface 21a. Practically, the back bezel 21 may be manufactured by stamping a metal sheet from a surface thereof to form the recessed area 21b.

The base 22 is disposed correspondingly in the recessed area 21b, and has a bottom portion 221 and a fixing portion 222. The bottom portion 221 has a top surface 221a and a bottom surface 221b. Because the bottom portion 221 is relatively disposed in the recessed area 21b of the back bezel 21, the top surface 221a of the bottom portion 221 is capable of adjoining to the top surface 21a of the back bezel 21. The top surface 221a of the bottom portion 221 should be flushed with the surface 21a of the back bezel 21 so that partial bulging of the covered reflecting sheet 23, which would otherwise degrade optical reflectivity, can be prevented. On the other hand, the base 22 can be secured to the back bezel 21 in several ways. For example, the base 22 can be adhered to the recessed area 21b of the base 22 by applying an adhesive to the bottom surface 221b of the bottom portion 221. The base 22 may further comprise a clamp 223 disposed on the bottom surface 221b of the bottom portion 221, which is adapted to be snapped into a prefabricated through-hole 21c of the back bezel 21 to detachably secure the base 22.

Furthermore, the fixing portion 222 is located on the side of the top surface 221a of the bottom portion 221 and has a plurality of lamp holders 222a, each of which extends outwards from the top surface 221a of the bottom portion 221 and protrudes beyond the surface 21a of the back bezel 21 after the base 22 is installed in the recessed area 21b. Each of the lamp holders 222a is adapted to hold a lamp 25 for use as a light source. In the preferred example, the fixing portion 222 may further comprise at least one spacer pin 222b. The spacer pin 222b extends outwards from the top surface 221a of the bottom portion 221 and protrudes beyond the top surface 21a of the back bezel 21 after the base 22 is installed in the recessed area 21b. The spacer pin 222b is adapted to support an optical film set 24 to keep a predetermined distance between the optical film set 24 and the back bezel 21 in the backlight module 2.

It should be noted that the number of each kind of elements in this figure may vary according to practical applications. For instance, the backlight module 2 may have a plurality of recessed areas 21b and a plurality of bases 22. Each of the recessed areas 21b may be provided with a single base 22 or a plurality of bases 22 therein; i.e., the bottom portions 221 of the bases 22 may be separated from each other or connected with each other to form an integral base. Additionally, the number of lamp holders 222a and spacer pins 222b in he fixing portion 222 may be optionally adjusted to achieve the optimal optical effect and structural support effect.

Additionally, the reflecting sheet 23 of the backlight module 2 of this invention is attached to the surface 21a of the back bezel 21 and also to the top surface 221a of the base 22 to increase the reflective area on the back bezel 21. The reflecting sheet 23 has at least one opening 23a, which is adapted to expose the lamp holders 222a and the spacer pins 222b after the reflecting sheet 23 is attached on the back bezel 21 and the base 22.

This invention further provides a method for manufacturing the back bezel 21 described above. Initially, a metal sheet is provided and put into a stamping die. Then, the metal sheet is stamped inwards from the surface thereof in such a way that the surface is recessed inwards to form the recessed areas 21b. The size, shape and number of recessed areas 21b may vary according to the number and positions of the bases actually needed. It should be appreciated that other details on how this back bezel is manufactured are just the same as those of the method for manufacturing conventional back bezels and thus will not be further described herein.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A backlight module structure, comprising:
a back bezel, having a surface and a recessed area extending inward from the surface; and
a base, including:
at least one bottom portion disposed on the recessed area; and
at least one fixing portion disposed on the at least one bottom portion, extending outward from the at least one bottom portion and protruding above the surface.

2. The backlight module structure as claimed in claim 1, wherein the base comprises a plurality of the bottom portions and a plurality of the fixing portions, each of the fixing portions is correspondingly disposed on each of the bottom portions, and extends outward from the bottom portion and protrudes above the surface of the back bezel.

3. The backlight module structure as claimed in claim 2, further comprising a reflecting sheet having a plurality of openings disposed on the reflecting sheet, wherein when the reflecting sheet is attached to the surface of the back bezel, the reflecting sheet is adapted to cover the top surface of the bottom portions and the fixing portions are adapted to protrude outward through the openings.

4. The backlight module structure as claimed in claim 3, wherein at least one of the fixing portions comprises at least one lamp holder adapted to hold a lamp.

5. The backlight module structure as claimed in claim 3, further comprising an optical film set disposed above the reflecting sheet.

6. The backlight module structure as claimed in claim 5, wherein at least one of the fixing portions comprises at least one spacer pin disposed on the corresponding bottom portion and adapted to support the optical film set.

7. The backlight module structure as claimed in claim 6, wherein the at least one of the fixing portions further comprises at least one lamp holder adapted to hold a lamp.

8. The backlight module structure as claimed in claim 2, wherein each of the bottom portions has a bottom surface adhered to the recessed area by adhesive.

9. The backlight module structure as claimed in claim 2, wherein
the recessed area has a plurality of through holes, each of the bottom portions has a bottom surface and at least one clamp, and the at least one clamp is disposed on the bottom surface correspondingly and adapted to be embedded in the recessed area by snapping into one of the through holes to secure the corresponding bottom portion onto the recessed area.

10. The backlight module structure as claimed in claim 2, wherein each of the bottom portions has a top surface substantially at a level the same as that of the surface of the back bezel.

11. The backlight module structure as claimed in claim 2, wherein the bottom portions are connected to each other to form a base integrally.

12. The backlight module structure as claimed in claim 11, further comprising a reflecting sheet having a plurality of openings disposed on a side of the reflecting sheet, wherein when the reflecting sheet is attached to the surface of the back bezel, the side of the reflecting sheet is adapted to cover the top surface of the base and the fixing portions are adapted to protrude outward through the openings.

13. The backlight module structure as claimed in claim 12, wherein at least one of the fixing portions comprises at least one lamp holder adapted to hold a lamp.

14. The backlight module structure as claimed in claim 12, further comprising an optical film set disposed above the reflecting sheet.

15. The backlight module structure as claimed in claim 14, wherein at least one of the fixing portions comprises at least one spacer pin, the at least one spacer pin is disposed on the at least one bottom portion, extending outward from the at least one bottom portion, protruding above the surface, and adapted to support the optical film set.

16. The backlight module structure as claimed in claim 15, wherein the at least one of the fixing portions further comprises at least one lamp holder adapted to hold a lamp.

17. The backlight module structure as claimed in claim 11, wherein the base has a bottom surface adhered to the recessed area by adhesive.

18. The backlight module structure as claimed in claim 11, wherein
the recessed area has a plurality of through holes, the base has a bottom surface and at least one clamp, the at least one clamp is disposed on the bottom surface and adapted to be embedded in the recessed area by snapping into one of the through holes to secure the base onto the recessed area.

19. The backlight module structure as claimed in claim 11, wherein the base has a top surface substantially at a level the same as that of the surface of the back bezel.

20. A back bezel for use in a backlight module, having a surface and a recessed area, the recessed area extending inward from the surface and adapted to receive at least one part of the base.
